(19) United States
(12) Patent Application Publication
(10) Pub. No.: US 2005/0157536 A1
(43) Pub. Date: Jul. 21, 2005

(54) Semiconductor device including nonvolatile memory and method of fabricating the same

(75) Inventor: Shota Kitamura, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/999,135

(22) Filed: Nov. 30, 2004

(30) Foreign Application Priority Data
Dec. 1, 2003 (JP) P2003-401854

(51) Int. Cl. G11C 11/00

(52) U.S. Cl. 365/154

(57) ABSTRACT

A semiconductor device including a nonvolatile memory and the fabrication method of the semiconductor device is described. There is provided a semiconductor device, including a semiconductor substrate, a nonvolatile memory cell including a first MOS transistor having a first gate formed on the semiconductor substrate, and source-drain regions formed in the semiconductor substrate to interpose a surface region of the semiconductor substrate beneath the first gate, the first gate being a layered gate structure having a tunnel gate insulating film, a first gate electrode film, an inter-gate insulating film and a second gate electrode film, and a logic circuit including a second MOS transistor having a second gate formed on the semiconductor substrate, and the source-drain regions formed in the semiconductor substrate to interpose a surface region of the semiconductor substrate beneath the second gate, the second gate being a gate structure having a gate insulating film, the first gate electrode film and the second gate electrode film.

### CROSS REFERENCE TO RELATED APPLICATION

This application is based upon and claims the benefit of priority from the prior Japanese Patent Application (No.2003-401854, filed on Dec. 1, 2003), the entire contents of which are incorporated herein by reference.

### FIELD OF THE INVENTION

The present invention relates to a semiconductor device including a nonvolatile memory and a method of fabricating the semiconductor device.

### DESCRIPTION OF THE BACKGROUND

A NAND-type flash memory and a NOR-type flash memory have been widely used as nonvolatile memory devices. In recent years, flash memory devices having advantages of both a NAND-type flash memory and a NOR-type flash memory have been proposed. The demand for a system LSI including flash memory circuits as well as logic circuits has also increased.

The system LSI including flash memory circuits and logic circuits have a complicated device structure. A gate structure of a flash memory cell differs from that of a MOS transistor used in a logic circuit. The flash memory cell has a gate structure, which is generally provided with double gate electrodes, while the MOS transistor has single gate electrode.

Moreover, fabrication steps of the flash memory cell partially differ from those of the MOS transistor used in the logic circuit. For example, the storage characteristics are important for a gate insulating film of the flash memory cell. On the other hand, the reduction of gate capacitance is necessary for a gate insulating film of the MOS transistor being used in the logic circuit. In the system LSI, it is required to satisfy performances of both the flash memory cell and the logic circuit.

Furthermore, it is also required, in the system LSI, to adjust fabrication steps and a device structure between the flash memory cell and the logic circuit or to fix an order of process priority between the flash memory cell and the logic circuit.

Japanese Patent Publication (Kokai) No.2002-64157 discloses a device structure and fabrication method of LSI including both a flash memory and a periphery logic circuit. For example, a tunnel gate insulating film of a flash memory cell is formed before an element isolation formation for a device structure and a fabrication method, when prioritizing the performance of a tunnel gate insulating film in the flash memory cell.

As mentioned above, the LSI having more excellent performance can be fabricated by adjusting the device structure and the fabrication method between the flash memory and the periphery logic circuit.

However, further improvement is required for higher speed performance of a logic circuit in a future system LSI including a flash memory and a logic circuit.

### SUMMRY OF THE INVENTION

According to an aspect of the present invention, there is provided a semiconductor device including, a semiconductor substrate, a nonvolatile memory cell including a first MOS transistor having a first gate formed on the semiconductor substrate, and source-drain regions formed in the semiconductor substrate to interpose a surface region of the semiconductor substrate beneath the first gate, the first gate being a layered gate structure having a tunnel gate insulating film, a first gate electrode film, an inter-gate insulating film and a second gate electrode film, and a logic circuit including a second MOS transistor having a second gate formed on the semiconductor substrate, and the source-drain regions formed in the semiconductor substrate to interpose a surface region of the semiconductor substrate beneath the second gate, the second gate being a gate structure having a gate insulating film, the first gate electrode film and the second gate electrode film.

According to another aspect of the present invention, there is provided a method of fabricating a semiconductor device including, forming an element isolation area surrounding an element area in a semiconductor substrate, forming a tunnel gate insulating film on the element area, removing the tunnel gate insulating film on a logic circuit region having CMOS logic circuits in the element area, forming a gate insulating film on the logic circuit region in the element area, forming a first gate electrode film on the tunnel gate insulating film and the gate insulating film, selectively removing the first gate electrode film and the tunnel gate insulating film on the nonvolatile memory cell region in the element area, forming an inter-gate insulating film on the first gate electrode film of the nonvolatile memory cell region, forming a second gate electrode film on the inter-gate insulating film of the nonvolatile memory cell region and the first gate electrode film of the logic circuit region, introducing conductive impurities into the second gate electrode film, selectively removing the second gate electrode film, the inter-gate insulating film and the first gate electrode film of the nonvolatile memory cell region, and the second gate electrode film and the first gate electrode film of the logic circuit region, and forming source-drain regions in the semiconductor substrate to interpose a surface region of the semiconductor substrate beneath the tunnel gate insulating film and the gate insulating film, by introducing conductive impurities into the semiconductor substrate using the second gate electrode film as a mask.

### BRIEF DESCRIPTION OF THE DRAWINGS

FIG. 1 is a circuit block diagram showing a nonvolatile memory according to a first embodiment of the present invention;

FIG. 2 is a schematic plane view showing the nonvolatile memory according to the first embodiment of the present invention;

FIGS. 3A to 3R are cross-sectional views showing a fabrication method of a semiconductor device according to the first embodiment of the present invention;

FIGS. 4A to 4R are cross-sectional views showing a fabrication method of a semiconductor device according to the second embodiment of the present invention;

FIG. 5 is a circuit block diagram showing the nonvolatile memory according to a third embodiment of the present invention;

FIGS. 6A to 6L are cross-sectional views showing a fabrication method of a semiconductor device according to the third embodiment of the present invention;

FIG. 7 is a cross-sectional view showing a semiconductor device according to the third embodiment of the present invention;

FIG. 8 is a block diagram showing a system LSI according to a fourth embodiment of the present invention;

FIG. 9 is a circuit block diagram showing a nonvolatile memory included in the system LSI according to the fourth embodiment of the present invention; and

FIG. 10 is a circuit block diagram showing a nonvolatile memory included in the system LSI according to the fourth embodiment of the present invention.

### DETAILED DESCRIPTION OF THE INVENTION

Embodiments of the present invention will be described hereinafter in detail with reference to the drawings mentioned above.

A first embodiment of the present invention is hereinafter explained. The first embodiment of the present invention includes a flash memory having a memory cell formed of two first MOS transistors. The first MOS transistor has a first gate of a layered structure. The layered structure includes a tunnel insulating film, a first gate electrode film for a floating gate electrode film, an inter-gate insulating film and a second gate electrode film for a control gate electrode film.

On the other hand, the first embodiment of the present invention also includes a logic circuit. The logic circuit contains a CMOS logic circuit having a second MOS transistor. The second MOS transistor has a second gate of a layered structure. The layered structure includes a first gate insulating film, a first gate electrode film and a second gate electrode film.

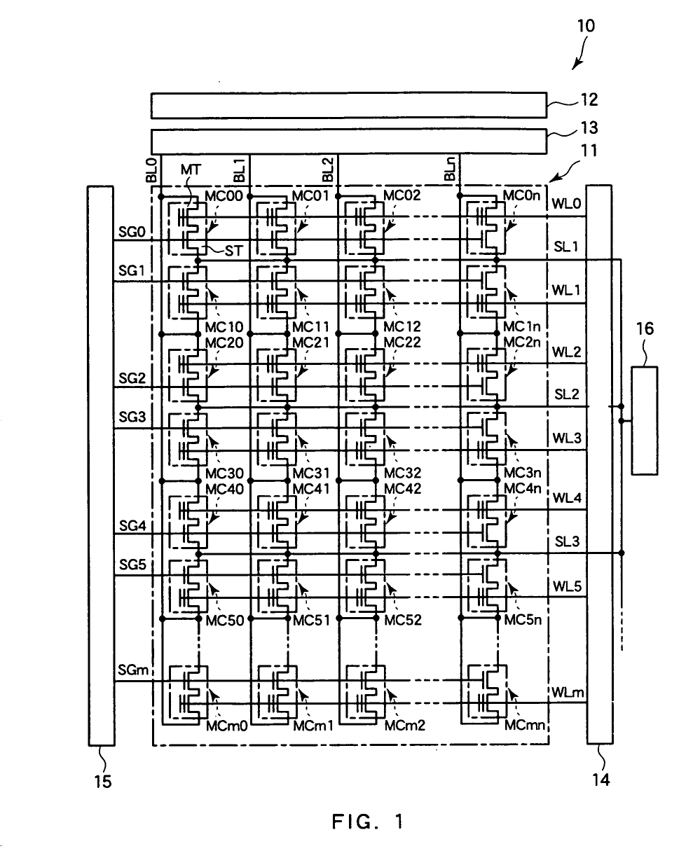

FIG. 1 shows a block diagram of the nonvolatile memory in the first embodiment of the present invention. A nonvolatile memory 10 has a memory cell array 11, a column decoder 12, a sense amplifier 13, low decoders 14 and 15, and a source line driver 16.

The memory cell array 11 includes a plurality of memory cells MC. Each of the memory cells MC has a memory cell transistor MT and a select transistor ST. The electrical current path of the memory cell transistor MT and the select transistors ST is connected with each other in series. The source region of the memory cell transistor MT connects to the drain region of the select transistor ST. Moreover, each of the memory cells MC adjoining mutually in the column direction share the source region of the select transistor ST.

Each control gate of the memory cell transistors MT in the row direction is connected in common with a word line WL. Each gate of the select transistors ST in the row direction is connected in common with a select gate line SG. Each drain region of the memory cell transistors MT is arranged in the column direction and is connected in common with a bit line. Each source region of select transistors ST is connected in common with the source line SL. The source line SL is connected to the source line driver 16.

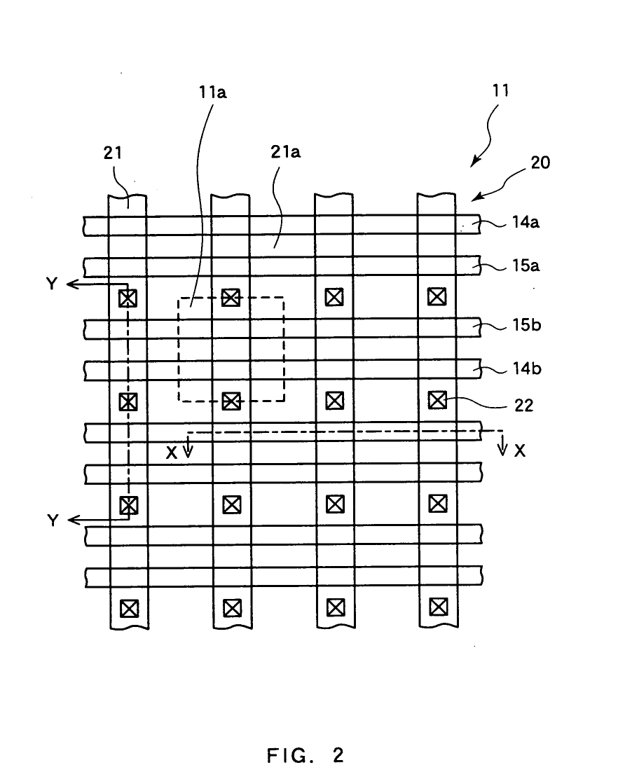

FIG. 2 shows a schematic plane view of a memory cell array 11. An element area 21 and an element isolation area 21a adjoined the element area 21 are formed in a silicon substrate 20. Word lines 14a and 14b and select gate lines 15a and 15b, formed of the first gate electrode film, are made in the memory cell array 11. The word lines 14a and 14b and the select gate lines 15a and 15b extend perpendicularly and cross over the element area 21.

The memory cell transistor MT is formed at the portion where the word lines 14a or 14b intersects the element area 21. The select transistors ST are formed at the portion where the select gate line 15a or 15b intersects the element area 21.

A floating gate electrode film (not illustrated) is formed at the portion where the word line 14a or 14b intersects the elememt area 21. The floating gate electrode film made of a second gate electrode film, in a memory cell transistor is electrically isolated from that in another memory cell transistor.

Contact plugs 22 of the element region 21 sandwich the word line 14a and the select gate line 15a, and the word line 14b and the select gate line 15b. Bit lines (not illustrated) are formed along with the element area 21. The bit line and the memory cell transistor connect through contact plugs 22. The memory cell transistor MT and the select transistor ST, which are sandwiched by two of the contact plugs 22, form a memory cell unit 11a.

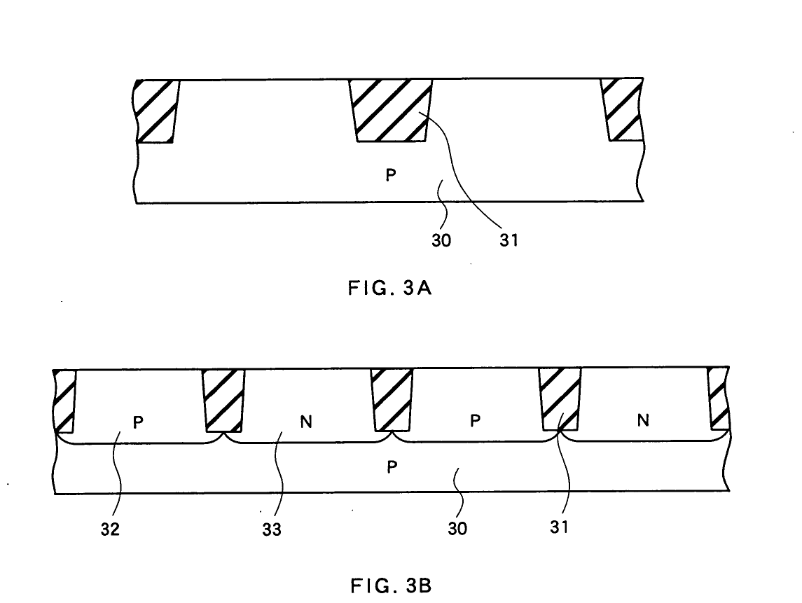

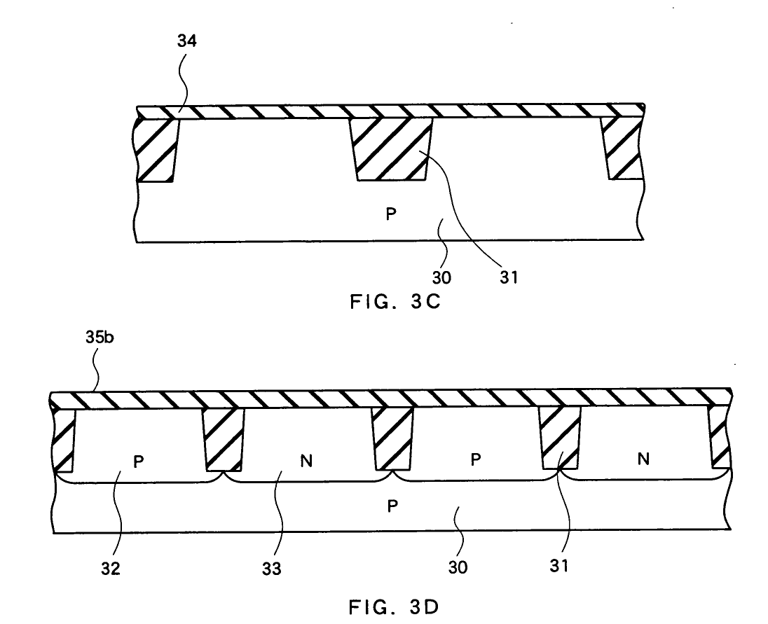

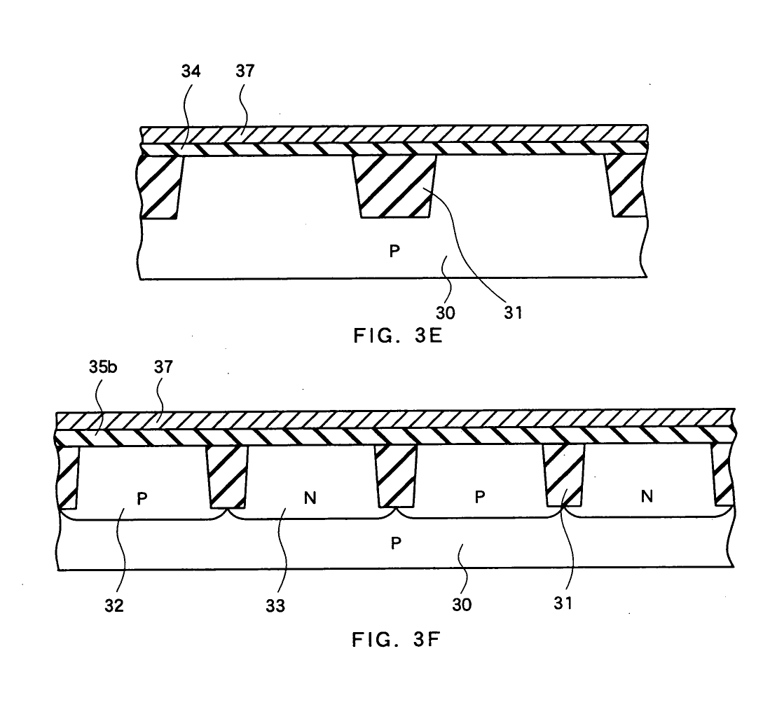

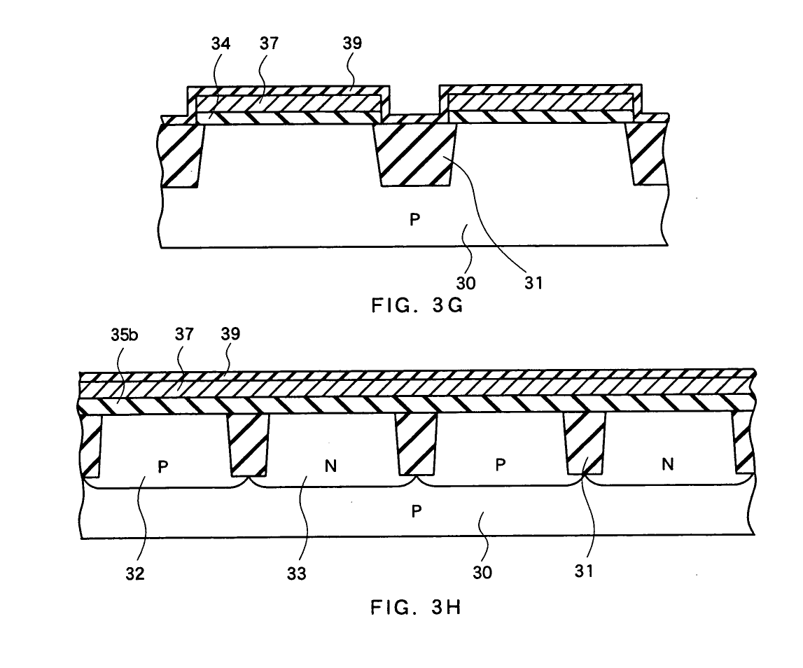

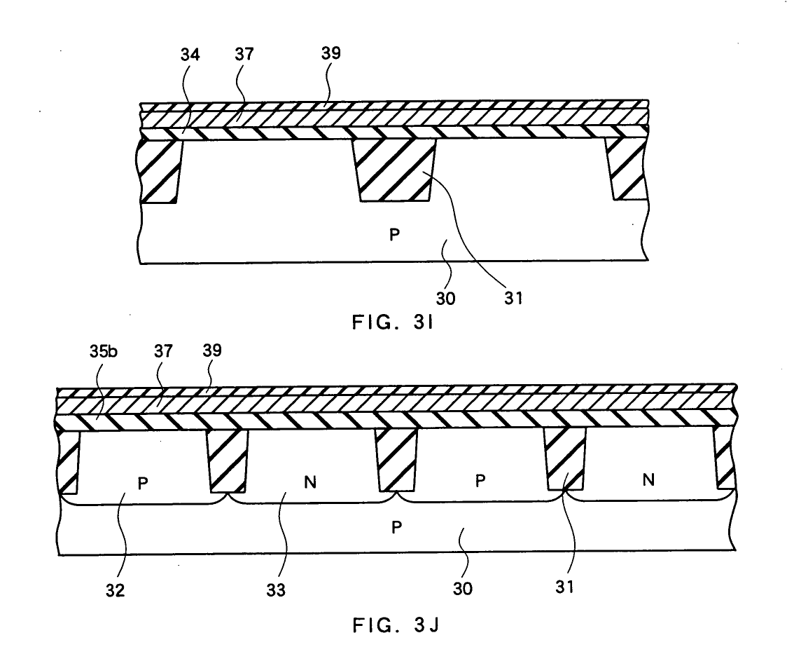

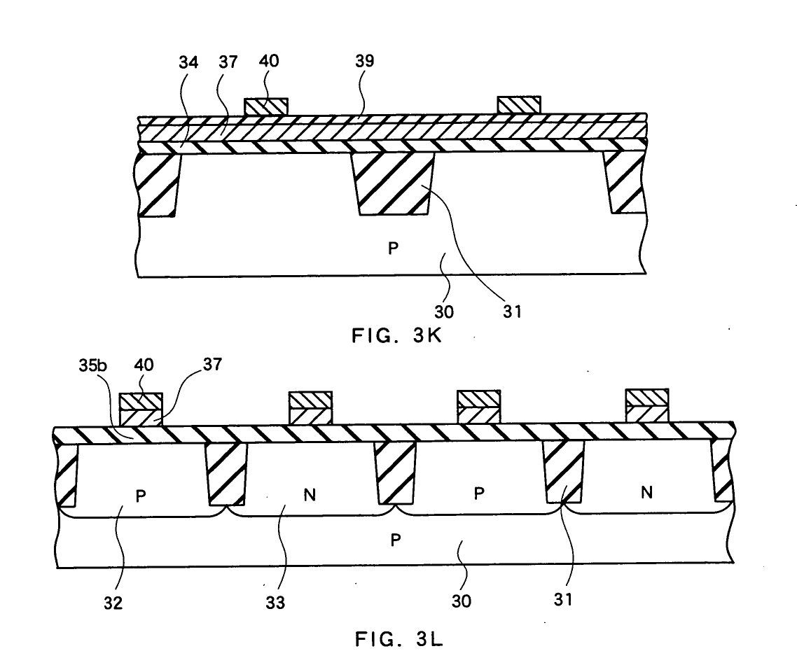

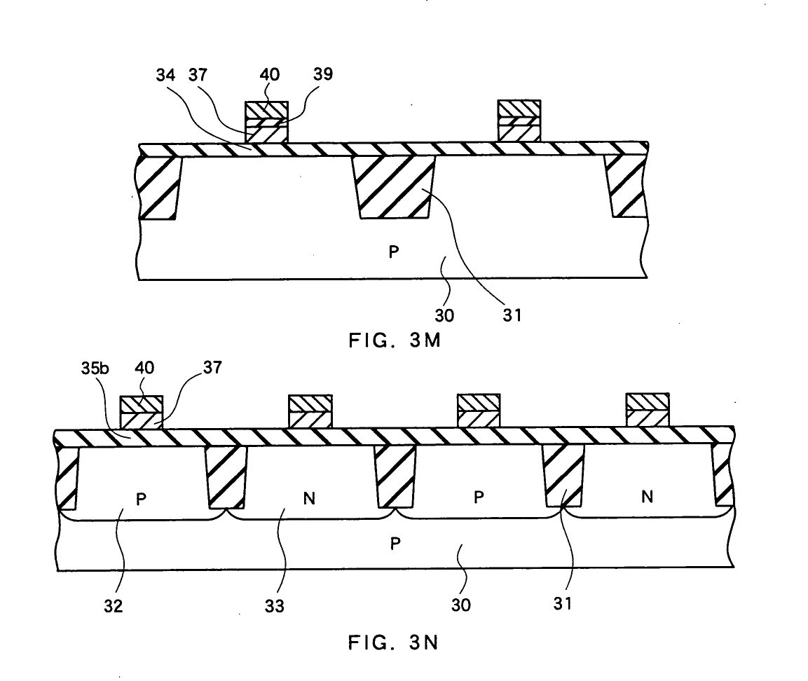

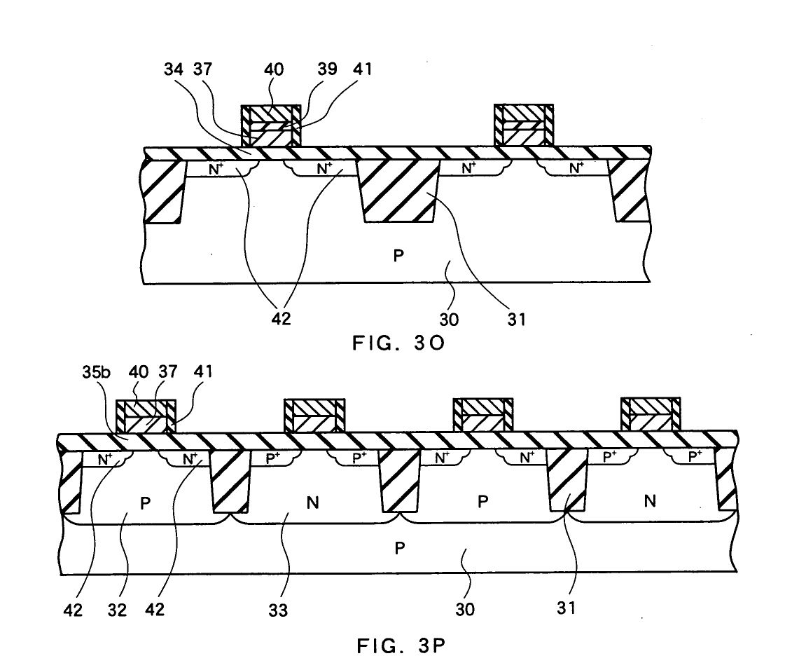

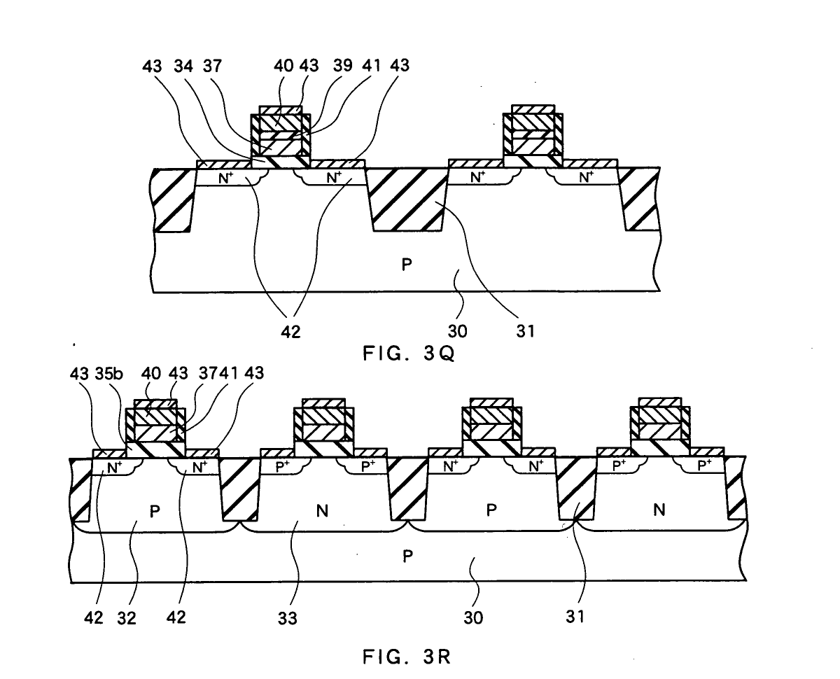

FIGS. 3A to 3R are cross sectional views showing a fabrication method of a semiconductor device in the first embodiment of the present invention. Pairs of a nonvolatile memory cell and a CMOS logic circuit are shown in FIGS. 3A to 3R. In other word, FIGS. 3A, 3C, 3E, 3G, 3I, 3K, 3M, 3O and 3Q show the cross sectional views of the nonvolatile memory cell. On the other hand, FIGS. 3B, 3D, 3F, 3H, 3J, 3L, 3N, 3P and 3R show the cross-sectional views of the CMOS logic circuit. Moreover, FIGS. 3Q and 3R show cross-sectional views of a semiconductor device in the first embodiment of the present invention.

Along with the steps of the fabrication processes, cross-sectional views of the nonvolatile memory cell are described below. FIGS. 3A, 3C, 3E and 3G enlarged cross sectional views along the line X-X of FIG. 2. FIGS. 3I, 3K, 3M, 3O and 3Q enlarged cross sectional views along the line Y-Y of FIG. 2. On the contrary, cross sectional views of the CMOS logic circuit in FIGS. 3B, 3D, 3F, 3H, 3J, 3L, 3N, 3P and 3R are shown without changing the cross-sectional direction.

First, steps of forming an element isolation area are explained blow. As shown in FIG. 3A and 3B, a p-type silicon substrate 30 is prepared as a semiconductor substrate. A layered film of a silicon oxide film and a silicon nitride film, which are not illustrated, are formed on silicon substrate 30. The layered film is selectively delineated by using lithography and dry etching. As a result, a layered pattern (not illustrated) is formed on the silicon substrate 30. Successively, a groove (not illustrated) is formed in the silicon substrate 30 by using dry etching, employing the layered pattern as a mask.

A silicon oxide film is formed on silicon substrate 30 including the groove by using CVD. The silicon oxide film and the layered pattern formed on silicon substrate 30 are removed flatly by using CMP and etching, and the silicon oxide film formed in the groove remains as shown in FIG. 3A. The groove embedded with the silicon oxide film is an element isolation area 31.

Furthermore, a p-type well 32 and an n-type well 33 are formed in a CMOS logic circuit region, respectively, as shown in FIG. 3B. Boron ions for p-type impurities and phosphorus ions or arsenic ions for n-type impurities, respectively, are implanted with a dose of approximately 1 E 11 cm⁻² to 1 E 13 cm⁻² into the silicon substrate 30 by using lithography and ion implantation. Subsequent thermal annealing activates the implanted impurities. A p-type impurities may be not introduced into the p-type well 32, as the silicon substrate 30 is a p-type silicon. A double well structure embedded the p-type well in an n-type well also may be utilized in a high-voltage transistor region.

Steps of forming a channel structure of the nonvolatile memory cell and the CMOS logic circuit are explained blow. A channel region of each MOS transistor is formed. Boron ion for p-type impurity and phosphorus ion or arsenic ion for n-type impurity are implanted into the n-type well 33 and the p-type well 32, respectively, by using lithography and ion implantation.

Steps of forming a gate structure of the nonvolatile memory cell region and the CMOS logic circuit region are explained blow. A silicon oxide film having a thickness of such as 8 nm is thermally grown on the silicon substrate 30. The silicon oxide film in the CMOS logic circuit region is removed by using lithography and etching. As shown in FIG. 3C, the silicon oxide film in the nonvolatile memory cell region is remained for a tunnel gate insulating film 34. As shown in FIG. 3D, a gate insulating film 35b having a thickness of such as 3 nm is thermally grown on the silicon substrate 30 of the CMOS logic circuit region.

A polycrystalline silicon film or an amorphous silicon film having a thickness of such as 50 nm is deposited on the tunnel gate insulating film 34 and the gate insulating film 35b by using CVD to form a first gate electrode film 37 as shown in FIGS. 3E and 3F. The CMOS logic circuit region is covered with a resist film or an insulating film as a mask film (not illustrated). The first gate electrode film 37 and the tunnel gate insulating film 34 in the nonvolatile memory cell region are selectively delineated by using lithography and dry etching. Accordingly, A layered structure having the first gate electrode film 37 stacked on the tunnel gate insulating film 34 is formed in the nonvolatile memory cell region. The mask film, i.e. the resist film or an insulating film, in the CMOS logic circuit region is removed by etching.

As shown in FIG. 3G and 3H, an inter-gate insulating film 39 of the nonvolatile memory cell is formed over the silicon substrate 30. The inter-gate insulating film 39 may be a layered structure including a plurality of insulating films. For example, a silicon oxide film, a silicon nitride film, and another silicon oxide film are continuously formed in the same CVD equipment. The whole film thickness of the layered structure is such as approximately 15 nm.

The inter-gate insulating film 39 is also formed on the CMOS logic circuit region in FIG. 3H, but it is not used for the gate material in the CMOS logic circuit. The inter-gate insulating film 39 of the CMOS logic circuit is removed as mentioned later.

Steps of forming a transistor of the nonvolatile memory and the CMOS logic circuit are explained blow. FIG. 3I shows a cross sectional view along the line Y-Y of FIG. 2. and FIG. 3J shows the same step as the step shown in FIG. 3H. As shown in FIG. 3I, the layered structure of the tunnel gate insulating film 34, the first gate electrode film 37 and the inter-gate insulating film 39 is formed on the silicon substrate 30 in the Y-Y direction. The cross sectional view is used for explaining the steps fabricating the nonvolatile memory cell mentioned below. On the other hand, the cross sectional view of the CMOS logic circuit region is the same as the former step shown in FIG. 3H.

The nonvolatile memory cell region is covered with a resist film or an insulating film as a mask film (not illustrated). The inter-gate insulating film 39 in the CMOS logic circuit region is removed by using lithography, dry etching and wet etching. A polycrystalline silicon film or an amorphous silicon film of approximately 50 nm is formed in both the nonvolatile memory cell region and the CMOS logic circuit region by using CVD.

Conductive impurities are introduced into the polycrystalline silicon film or the amorphous silicon film. Boron ions for p-type impurities and phosphorus ions or arsenic ions for n-type impurities are implanted into n-channel transistors of the CMOS logic circuit region and the nonvolatile memory cell region, and p-channel transistors of the CMOS logic circuit region, respectively, with a dose of approximately 1 E 15 cm⁻² to 1 E 16 cm⁻² by using lithography and ion implantation. Subsequent thermal annealing activates the implanted impurities. The impurity doping into the polycrystalline silicon film or the amorphous silicon film mentioned above can be performed with a step of forming source-drain regions where conductive impurities is doped into the silicon substrate 30.

The CMOS logic circuit region is covered with a mask film (not illustrated). The polycrystalline silicon film or the amorphous silicon film in the nonvolatile memory cell region is selectively delineated by using lithography and dry etching. As a result, a second gate electrode film 40 is formed in the nonvolatile memory cell region as shown in FIG. 3K. Furthermore, the nonvolatile memory cell region is covered with a mask film (not illustrated). The second gate electrode film 40 and the first gate electrode film 37 are selectively delineated by using lithography and dry etching in the CMOS logic circuit region. As a result, a layered structure having the second gate electrode film 40 stacked on the first gate electrode film 37 in the CMOS logic circuit region is formed as shown in FIG. 3L. The mask film in the nonvolatile memory cell region is removed by wet etching or dry etching.

The CMOS logic circuit region is covered with a mask film (not illustrated). As shown in FIG. 3M, the inter-gate insulating film 39 and the first gate electrode film 37 in the nonvolatile memory cell region are selectively delineated by using lithography and dry etching, employing the second gate electrode film 40 as a mask. The mask film in the CMOS logic circuit region is removed by using wet etching or dry etching as shown in FIG. 3N.

Conductive impurities are introduced into silicon substrate 30 in both the nonvolatile memory cell region and the CMOS logic circuit region by using ion implantation, employing the second gate electrode film 40 as a mask. Source-drain regions with a comparatively shallow junction depth, i.e. extension regions (not illustrated), are formed. Boron ions for p-type impurities and phosphorus ions or arsenic ions for n-type impurities are implanted into p-channel transistors of the CMOS logic circuit region, and n-channel transistors of the CMOS logic circuit region and the nonvolatile memory cell region, respectively, with a dose of approximately 1 E 13 cm⁻² to 1 E 15 cm⁻² by using lithography and ion implantation. Subsequent thermal annealing activates the implanted impurities.

An insulating film such as a silicon nitride film is formed on the second gate electrode film 40 by using CVD. The surface region of the insulating film is removed by using dry etching. As a result, a sidewall insulating film 41 is selectively formed on a side surface of the layered structure as shown in FIGS. 3O and 3P.

The layered structure of the tunnel gate insulating film 34, the first gate electrode film 37, the inter-gate insulating film 39, and the second gate electrode film 40 is a first gate of the nonvolatile memory cell transistor as shown in FIG. 3O. Moreover, the layered structure of the gate insulating film 35b, the first gate electrode film 37 and the second gate electrode film 40 is a second gate of the CMOS logic circuit as shown in FIG. 3P.

Conductive impurities are introduced into the silicon substrate 30 in both the nonvolatile memory region and the CMOS logic circuit region by using ion implantation, employing the second gate electrode film 40 and the sidewall insulating film 41 as a mask. The source-drain regions with a comparatively deep junction depth are formed. Boron ions for p-type impurities and phosphorus ions or arsenic ions for n-type impurities are implanted into p-channel transistors of the CMOS logic circuit region, and n-channel transistors of the CMOS logic circuit region and the nonvolatile memory cell region, respectively, with a dose of approximately 1 E 15 cm⁻² to 1 E 16 cm⁻² by using lithography and ion implantation. Subsequent thermal annealing activates the implanted impurities. The source-drain regions 42 including also the comparatively shallow source-drain regions are finally formed as shown in FIGS. 3O and 3P.

A cobalt film is formed in both the nonvolatile memory cell region and the CMOS logic circuit region. A cap film, such as Ti or TiN, may be further formed on the cobalt film, as required. By subsequent thermal annealing, a cobalt-salicide electrode film 43 is formed on the second gate electrode film 40 and the source-drain regions 42 as shown in FIGS. 3Q and 3R.

A silicon oxide film (not illustrated) is formed on the silicon substrate 30 by using plasma-assisted CVD. Contact holes are opened in the silicon oxide film. A metal interconnection including bit lines is formed. Furthermore, the formation of the silicon oxide film, the contact holes, and the metal interconnection are carried out, as required. A multilevel interconnection can be formed.

The surface of the silicon substrate 30 is covered with a protective insulating film. Pad portions may be opened to complete a semiconductor device including the nonvolatile memory.

According to the first embodiment, the n-channel transistor of the CMOS logic circuit as well as the nonvolatile memory cell has the gate electrode of n-type silicon. On the other hand, the p-channel transistor of the CMOS logic circuit has the gate electrode of p-type silicon. As a result, the channel region of the MOS transistor is formed near the surface region of the silicon substrate in not only the n-channel transistors of the CMOS logic circuit but also the p-channel transistor of the CMOS logic circuit.

On the contrary, when the p-channel transistor of the CMOS logic circuit has the conventional gate electrode of n-type silicon, the channel region of the p-channel transistor is formed in the inner region of the silicon substrate. The operation speed of the CMOS logic circuit having the surface channel region is faster than that of the CMOS logic circuit having the inner channel region. Accordingly, a semiconductor device including the nonvolatile memory in the first embodiment can improve the operation speed of the CMOS logic circuit.

Furthermore, the second gate electrode film, including the gate electrode film of the CMOS logic circuit and the control gate electrode film of nonvolatile memory cell is formed at a comparatively later step in the fabrication method. Therefore, subsequent thermal processes are avoided and the gate structure is suitable for miniaturization of the transistor in the CMOS logic circuit. The performance of the CMOS logic circuit in the semiconductor device including the nonvolatile memory can be improved.

A device structure of a second embodiment in the present invention is nearly the same as that of the first embodiment. A different point from the first embodiment in the second embodiment is that a CMOS logic circuit has two kinds of gate insulating film thicknesses correspond to a supply voltage to be applied.

The second embodiment of the present invention is hereinafter explained. The second embodiment of the present invention includes a flash memory having a memory cell formed of two first MOS transistors. The first MOS transistor has a first gate of a layered structure. The layered structure includes a tunnel insulating film, a first gate electrode film for a floating gate electrode film, an inter-gate insulating film and a second gate electrode film for a control gate electrode film.

On the other hand, the second embodiment of the present invention also includes a logic circuit. The logic circuit contains a CMOS logic circuit having a second MOS transistor. The second MOS transistor has a second gate of a layered structure. The layered structure includes a first gate insulating film or a second gate insulating film, a first gate electrode film and a third gate electrode film.

The thickness of the first gate insulating film is thicker than that of the second gate insulating film. Each of the two kinds of film thicknesses corresponds to a supply voltage to be applied to each second MOS transistor. The first gate insulating film and the second gate insulating film of each second MOS transistor are formed for a high-voltage transistor and a low-voltage transistor, respectively.

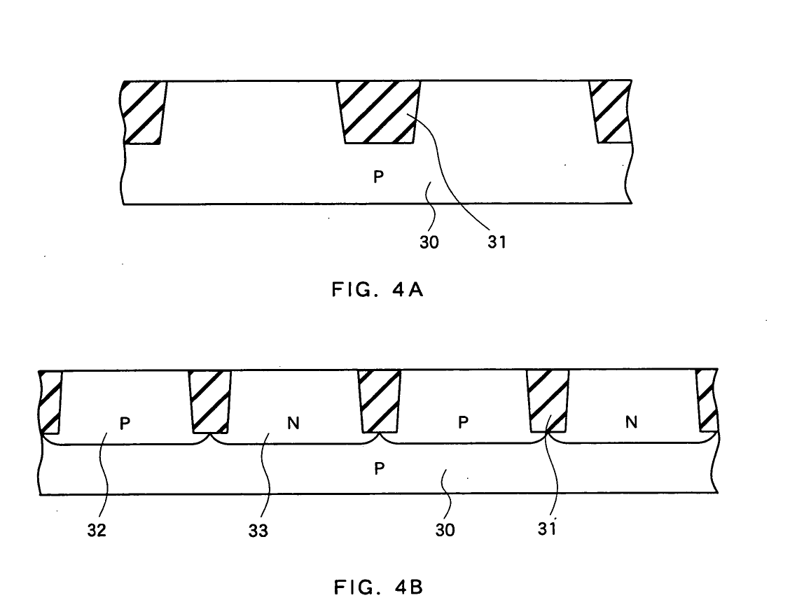

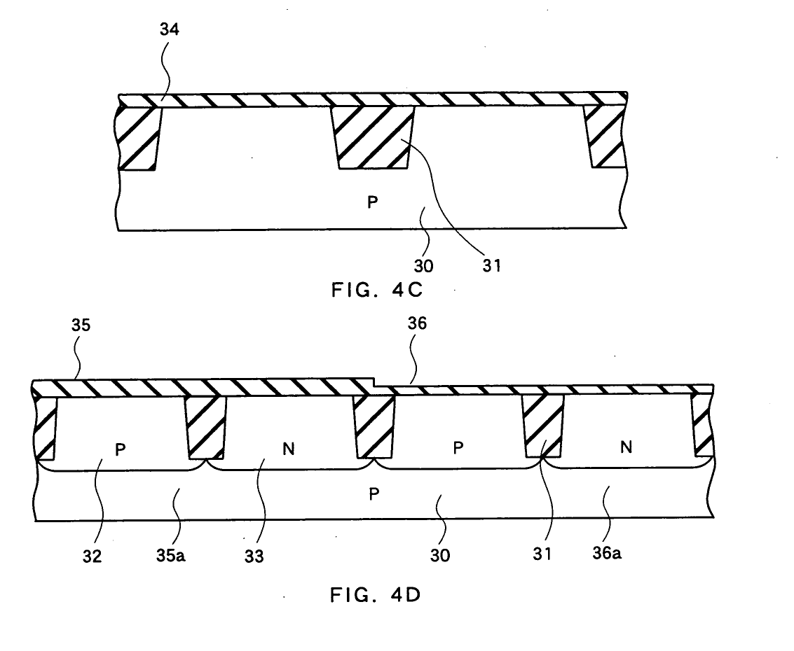

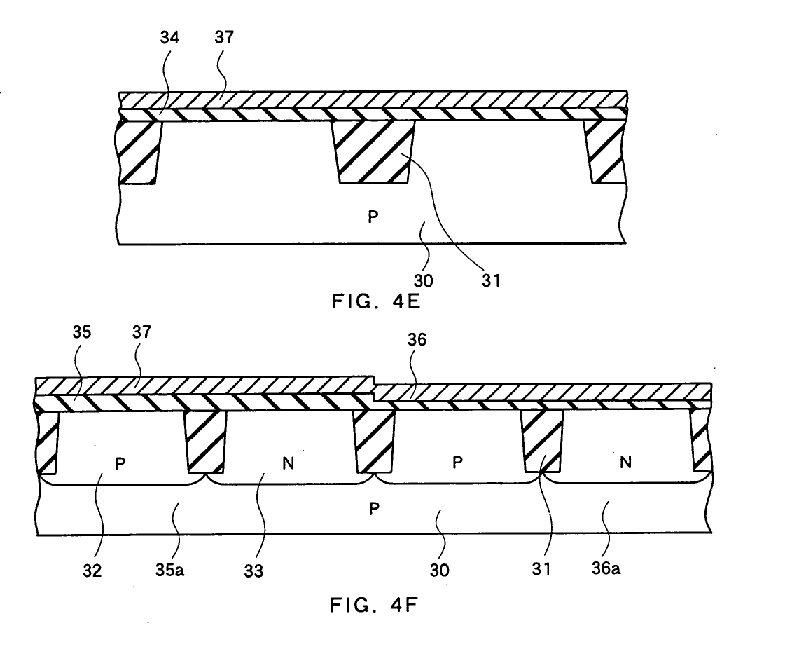

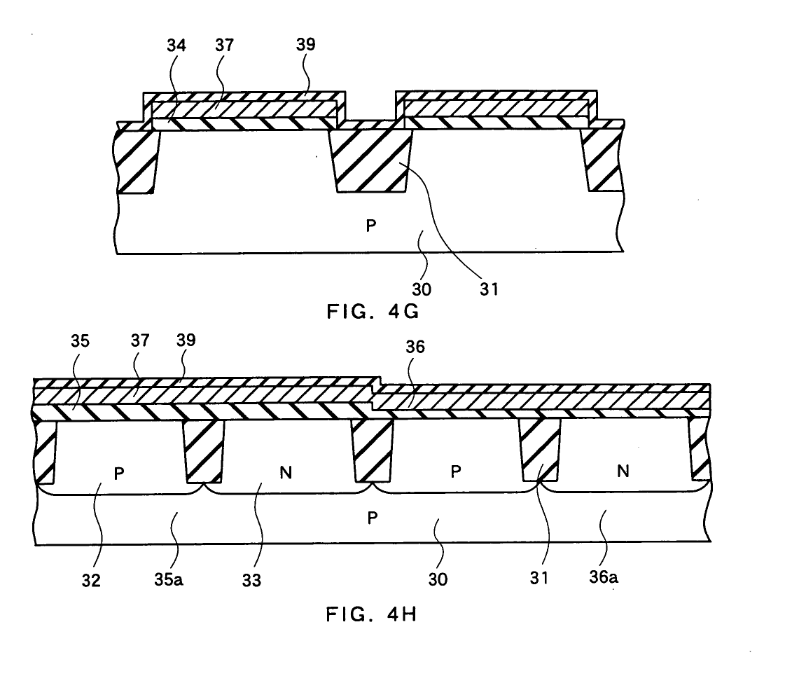

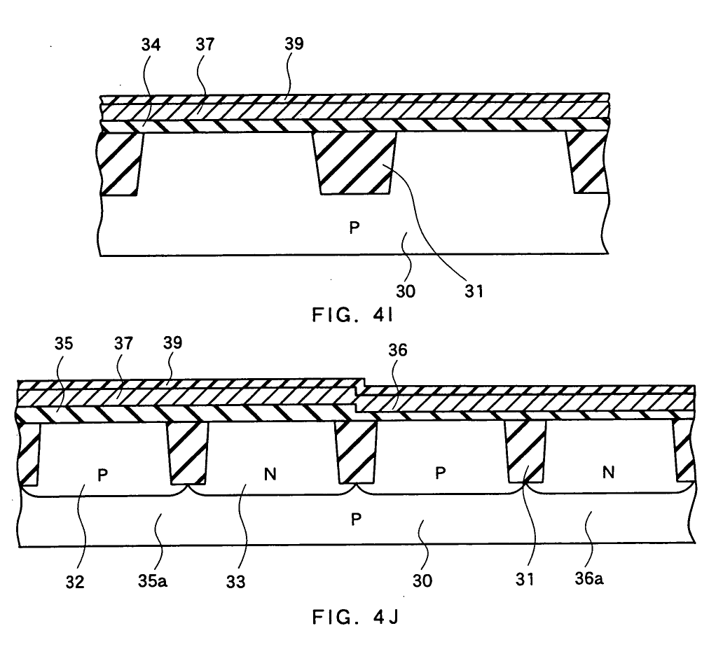

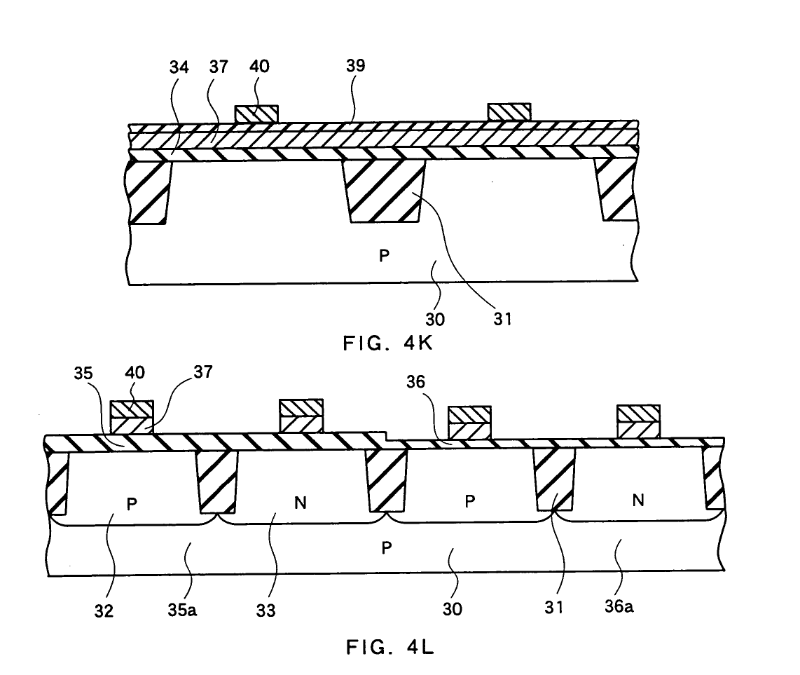

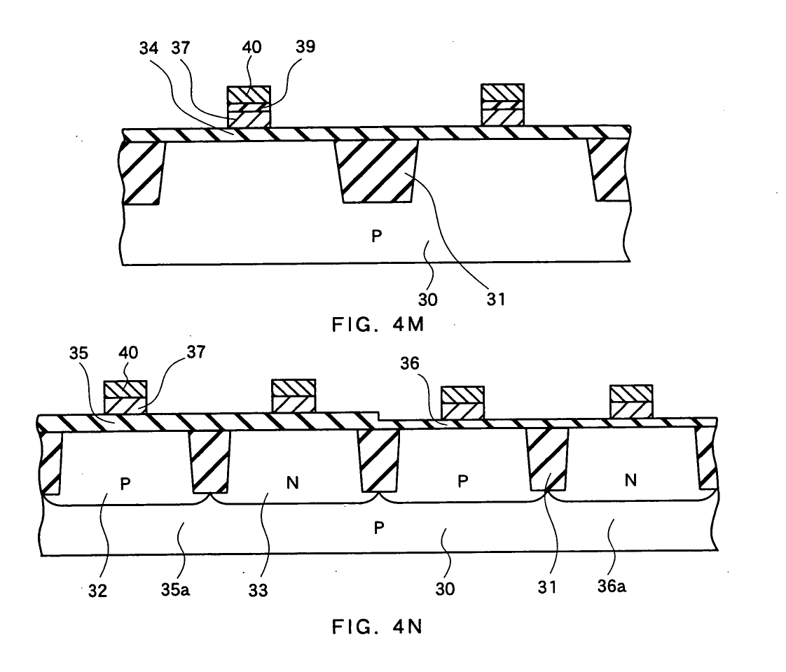

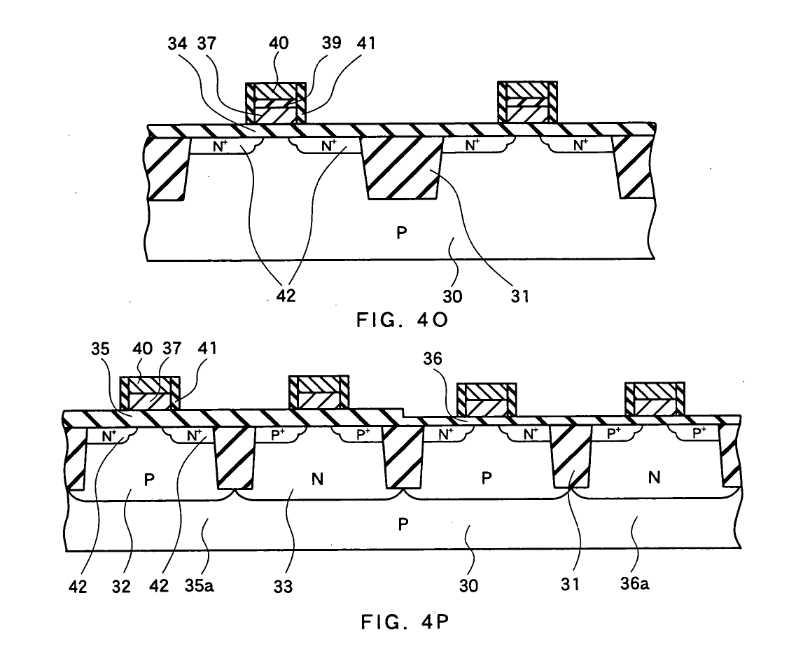

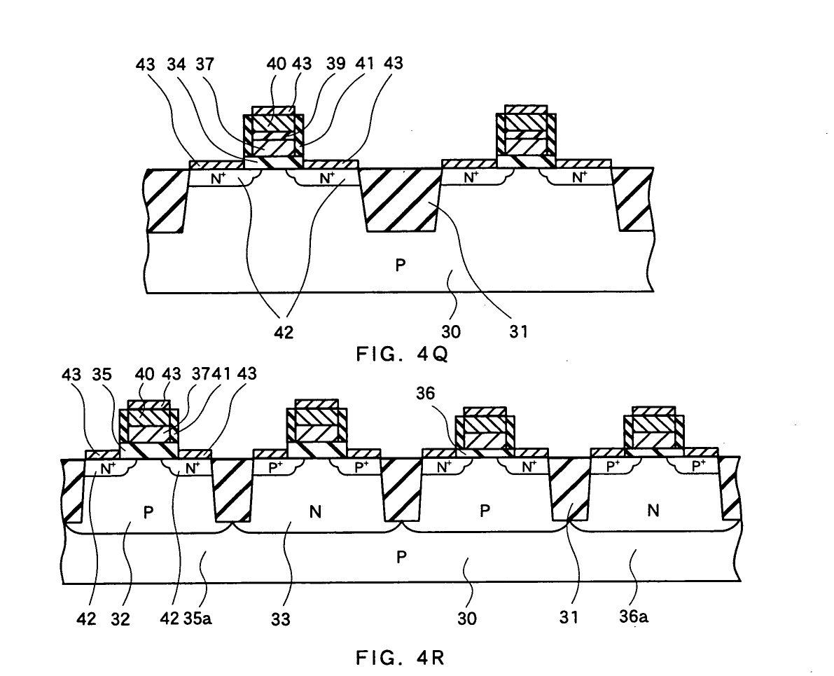

FIGS. 4A to 4R are cross sectional views showing a fabrication method of a semiconductor device in the second embodiment of the present invention. Pairs of a nonvolatile memory cell and a CMOS logic circuit are shown in FIGS. 4A to 4R. In other word, FIGS. 4A, 4C, 4E, 4G, 4I, 4K, 4M, 4O and 4Q show the cross sectional views of the nonvolatile memory cell. On the other hand, FIGS. 4B, 4D, 4F, 4H, 4J, 4L, 4N, 4P and 4R show the cross-sectional views of the CMOS logic circuit. Moreover, FIGS. 4Q and 4R show cross-sectional views of a semiconductor device in the second embodiment of the present invention.

Along with the steps of the fabrication processes, cross-sectional views of the nonvolatile memory cell are described below. FIGS. 4A, 4C, 4E and 4G enlarged cross sectional views along the line X-X of FIG. 2. FIGS. 4I, 4K, 4M, 4O and 4Q enlarged cross sectional views along the line Y-Y of FIG. 2. On the contrary, cross sectional views of the CMOS logic circuit in FIGS. 4B, 4D, 4F, 4H, 4J, 4L, 4N, 4P and 4R are shown without changing the cross-sectional direction.

First, steps of forming an element isolation area are explained blow. As shown in FIG. 4A and 4B, a p-type silicon substrate 30 is prepared as a semiconductor substrate. A layered film of a silicon oxide film and a silicon nitride film, which are not illustrated, are formed on silicon substrate 30. The layered film is selectively delineated by using lithography and dry etching. As a result, a layered pattern (not illustrated) is formed on the silicon substrate 30. Successively, a groove (not illustrated) is formed in the silicon substrate 30 by using dry etching, employing the layered pattern as a mask.

A silicon oxide film is formed on silicon substrate 30 including the groove by using CVD. The silicon oxide film and the layered pattern formed on silicon substrate 30 are removed flatly by using CMP and etching, and the silicon oxide film formed in the groove remains as shown in FIG. 4A. The groove embedded with the silicon oxide film is an element isolation area 31.

Furthermore, a p-type well 32 and an n-type well 33 are formed in a CMOS logic circuit region, respectively, as shown in FIG. 4B. Boron ions for p-type impurities and phosphorus ions or arsenic ions for n-type impurities, respectively, are implanted with a dose of approximately 1 E 11 cm⁻² to 1 E 13 cm⁻² into the silicon substrate 30 by using lithography and ion implantation. Subsequent thermal annealing activates the implanted impurities. A p-type impurities may be not introduced into the p-type well 32, as the silicon substrate 30 is a p-type silicon. A double well structure embedded the p-type well in an n-type well also may be utilized in a high-voltage transistor region.

Steps of forming a gate structure of the nonvolatile memory cell and the CMOS logic circuit are explained blow. A channel region of each MOS transistor is formed. Boron ion for p-type impurity and phosphorus ion or arsenic ion for n-type impurity are implanted into the n-type well 33 and the p-type well 32, respectively, by using lithography and ion implantation.

Steps of forming a channel structure of the nonvolatile memory cell region and the CMOS logic circuit region are explained blow. A silicon oxide film having a thickness of such as 8 nm is thermally grown on the silicon substrate 30. The silicon oxide film in the CMOS logic circuit region is removed by using lithography and etching. As shown in FIG. 4C, the silicon oxide film in the nonvolatile memory cell region is remained for a tunnel gate insulating film 34.

As shown in FIG. 4D, a first gate insulating film 35 and a second gate insulating film 36 are formed in the CMOS logic circuit region. First, a silicon oxide film having a thickness of such as 15 nm is thermally grown on silicon substrate 30. The silicon oxide film of a low-voltage transistor region is removed by using lithography and etching. The silicon oxide film of the high-voltage transistor region is remained for a first gate insulating film 35.

The second gate insulating film 36 having a thickness of such as 3 nm is thermally grown on the silicon substrate 30 of low-voltage transistor region. Finally, the tunnel gate insulating film 34, the first gate insulating film 35 and the second gate insulating film 36 have a thickness of approximately 8 nm, 15 nm and 3 nm, respectively. By employing fabrication steps mentioned above, a plurality of gate insulating films corresponding with a plurality of voltages to be applied in the CMOS logic circuits are formed.

A polycrystalline silicon film or an amorphous silicon film having a thickness of such as 50 nm is deposited on the tunnel gate insulating film 34, first gate insulating film 35 and the second gate insulating film 36 by using CVD to form a first gate electrode film 37 as shown in FIGS. 4E and 4F. The CMOS logic circuit region is covered with a resist film or an insulating film (not illustrated) as a mask film. The first gate electrode film 37 and the tunnel gate insulating film 34 in the nonvolatile memory cell region are selectively delineated by using lithography and dry etching. Accordingly, a layered structure having the first gate electrode film 37 stacked on the tunnel gate insulating film 34 is formed in the nonvolatile memory cell region. The mask film in the CMOS logic circuit region is removed by etching.

As shown in FIG. 4G and 4H, an inter-gate insulating film 39 of the nonvolatile memory cell is formed on the silicon substrate 30. The inter-gate insulating film 39 may be a layered structure including a plurality of insulating films. For example, a silicon oxide film, a silicon nitride film, and another silicon oxide film are continuously formed in the same CVD equipment. The whole film thickness of the layered structure is such as approximately 15 nm.

The inter-gate insulating film 39 is also formed on the CMOS logic circuit region in FIG. 4H, but it is not used for the gate material in the CMOS logic circuit. The inter-gate insulating film 39 of the CMOS logic circuit is removed as mentioned later.

Steps of forming a transistor of the nonvolatile memory and the CMOS logic circuit are explained blow. FIG. 4I shows a cross sectional view along the line Y-Y of FIG. 2. and FIG. 4J shows the same step as the step shown in FIG. 4H. As shown in FIG. 4I, the layered structure of the tunnel gate insulating film 34, the first gate electrode film 37 and the inter-gate insulating film 39 is formed on the silicon substrate 30 in the Y-Y direction. The cross sectional view is used for explaining the steps fabricating the nonvolatile memory cell mentioned below. On the other hand, the cross sectional view of the CMOS logic circuit region is the same as the former step shown in FIG. 4H.

The nonvolatile memory cell region is covered with a resist film or an insulating film as a mask film (not illustrated). The inter-gate insulating film 39 in the CMOS logic circuit region is removed by using lithography, dry etching and wet etching. A polycrystalline silicon film or an amorphous silicon film of approximately 50nm is formed in both the nonvolatile memory cell region and the CMOS logic circuit region by using CVD.

Conductive impurities are introduced into the polycrystalline silicon film or the amorphous silicon film. Boron ions for p-type impurities and phosphorus ions or arsenic ions for n-type impurities are implanted into n-channel transistors of the CMOS logic circuit region and the nonvolatile memory cell region, and p-channel transistors of the CMOS logic circuit region, respectively, with a dose of approximately 1 E 15 cm⁻² to 1 E 16 cm⁻² by using lithography and ion implantation. Subsequent thermal annealing activates the implanted impurities. The impurity doping into the polycrystalline silicon film or the amorphous silicon film mentioned above can be performed with an impurity doping into the silicon substrate 30.

The CMOS logic circuit region is covered with a mask film (not illustrated). The polycrystalline silicon film or the amorphous silicon film is selectively delineated by using lithography and dry etching. As a result, a second gate electrode film 40 is formed in the nonvolatile memory cell region as shown in FIG. 4K. Furthermore, the nonvolatile memory cell region is covered with a mask film (not illustrated). The second gate electrode film 40 and the first gate electrode film 37 in the CMOS logic circuit region are selectively delineated by using lithography and dry etching. As a result, a layered structure having the second gate electrode film 40 stacked on the first gate electrode film 37 in the CMOS logic circuit region is formed as shown in FIG. 4L.

The CMOS logic circuit region is covered with a mask (not illustrated). As shown in FIG. 4M, the inter-gate insulating film 39, the second gate electrode film 38 and the first gate electrode film 37 in the nonvolatile memory cell region are selectively delineated by using lithography and dry etching, employing the second gate electrode film 40 as a mask. The mask (not illustrated) in the CMOS logic circuit region is removed by using etching as shown in FIG. 4N. The mask film in the nonvolatile memory cell region is removed by wet etching or dry etching.

Conductive impurities are introduced into silicon substrate 30 in both the nonvolatile memory cell region and the CMOS logic circuit region by using ion implantation, employing the second gate electrode film 40 as a mask. Source-drain regions with a comparatively shallow junction depth, i.e. extension regions (not illustrated), is formed. Boron ions for p-type impurities and phosphorus ions or arsenic ions for n-type impurities are implanted into p-channel transistors of the CMOS logic circuit region, and n-channel transistors of the CMOS logic circuit region and the nonvolatile memory cell region, respectively, with a dose of approximately 1 E 13 cm⁻² to 1 E 15 cm⁻² by using lithography and ion implantation. Subsequent thermal annealing activates the implanted impurities.

An insulating film such as a silicon nitride film is formed on the second gate electrode film 40 by using CVD. The surface region of the insulating film is removed by using dry etching. As a result, a sidewall insulating film 41 is selectively formed on a side surface of the layered structure as shown in FIGS. 4O and 4P.

The layered structure of the tunnel gate insulating film 34, the first gate electrode film 37, inter-gate insulating film 39, and second gate electrode film 40 is a first gate of the nonvolatile memory cell transistor as shown in FIG. 4O. Moreover, the layered structure of the first gate insulating film 35 or the second gate insulating film 36, the first gate electrode film 37 and the second gate electrode film 40 is a second gate of the logic circuit as shown in FIG. 4P.

Conductive impurities are introduced into the silicon substrate 30 in both the nonvolatile memory region and the CMOS logic circuit region by using ion implantation, employing the second gate electrode film 40 and the sidewall insulating film 41 as a mask. The source-drain regions with a comparatively deep junction depth are formed. Boron ions for p-type impurities and phosphorus ions or arsenic ions for n-type impurities are implanted into p-channel transistors of the CMOS logic circuit region, and n-channel transistors of the CMOS logic circuit region and the nonvolatile memory cell region, respectively, with a dose of approximately 1 E 15 cm⁻² to 1 E 16 cm⁻² by using lithography and ion implantation. Subsequent thermal annealing activates the implanted impurities. The source-drain regions 42 including also the comparatively shallow source-drain regions are finally formed as shown in FIGS. 4O and 4P.

A cobalt film is formed in both the nonvolatile memory cell region and the CMOS logic circuit region. A cap film, such as Ti or TiN, may be further formed on the cobalt film, as required. By subsequent thermal annealing, a cobalt-salicide electrode film 43 is formed on the second gate electrode film 40 and the source-drain region 42 as shown in FIGS. 4Q and 4R.

A silicon oxide film (not illustrated) is formed on the silicon substrate 30 by using plasma-assisted CVD. Contact holes are opened in the silicon oxide film. A metal interconnection including bit lines is formed. Furthermore, the formation of the silicon oxide film, the contact holes, and the metal interconnection are carried out, as required. A multilevel interconnection can be formed.

The surface of the silicon substrate 30 is covered with a protective insulating film. Pad portions may be opened to complete a semiconductor device including the nonvolatile memory.

According to the second embodiment, the n-channel transistor of the CMOS logic circuit as well as the nonvolatile memory cell has the gate electrode of n-type silicon. On the other hand, the p-channel transistor of the CMOS logic circuit has the gate electrode of p-type silicon. As a result, the channel region of the MOS transistor is formed near the surface region of the silicon substrate in not only the n-channel transistors of the CMOS logic circuit but also the p-channel transistor of the CMOS logic circuit.

On the contrary, when the p-channel transistor of the CMOS logic circuit has the conventional gate electrode of n-type silicon, the channel region of the p-channel transistor is formed in the inner region of the silicon substrate. The operation speed of the CMOS logic circuit having the surface channel region is faster than that of the CMOS logic circuit having the inner channel region. Accordingly, a semiconductor device including the nonvolatile memory in the first embodiment can improve the operation speed of the CMOS logic circuit.

Furthermore, the second gate electrode film, including the gate electrode film of the CMOS logic circuit and the control gate electrode film of nonvolatile memory cell is formed at a comparatively later step in the fabrication method. Therefore, subsequent thermal processes are avoided and the gate structure is suitable for miniaturization of the transistor in the CMOS logic circuit. The performance of the CMOS logic circuit in the semiconductor device including the nonvolatile memory can be improved.

Moreover, the semiconductor device including the nonvolatile memory can advance the operation speed of the CMOS logic circuit by using two kinds of transistors. Each of the transistors has different film thicknesses of the gate insulating film corresponding to the supply voltage to be applied to the transistors.

A third embodiment of present invention is hereinafter explained. The basic structure of the third embodiment of this invention is nearly the same as that of the first embodiment. A different point from the first embodiment in the third embodiment is that an inter-gate insulating film to a nonvolatile memory cell region has an opening and a second gate electrode film is connected to a first gate electrode film through the opening.

The nonvolatile memory in the third embodiment is a flash memory having a memory cell formed of two first MOS transistors. The first MOS transistors have a first gate of a layered structure. The layered structure includes a tunnel insulating film, a first gate electrode film and for a floating gate electrode film, an inter-gate insulating film and a second gate electrode film for a control gate electrode film.

On the other hand, a logic circuit is also included in the third embodiment. The logic circuit contains a CMOS logic circuit having a second MOS transistor. The second MOS transistors have a second gate of a layered structure. The layered structure includes a first gate insulating film or a second gate insulating film, a first gate electrode film and a second gate electrode film.

The first gate insulating film thickness is thicker than the second gate insulating film thickness. Each of the two kinds of film thicknesses corresponds to a supply voltage to be applied to each second MOS transistor. The first gate insulating film and the second gate insulating film of each second MOS transistor are formed for a high-voltage and a low-voltage transistor, respectively.

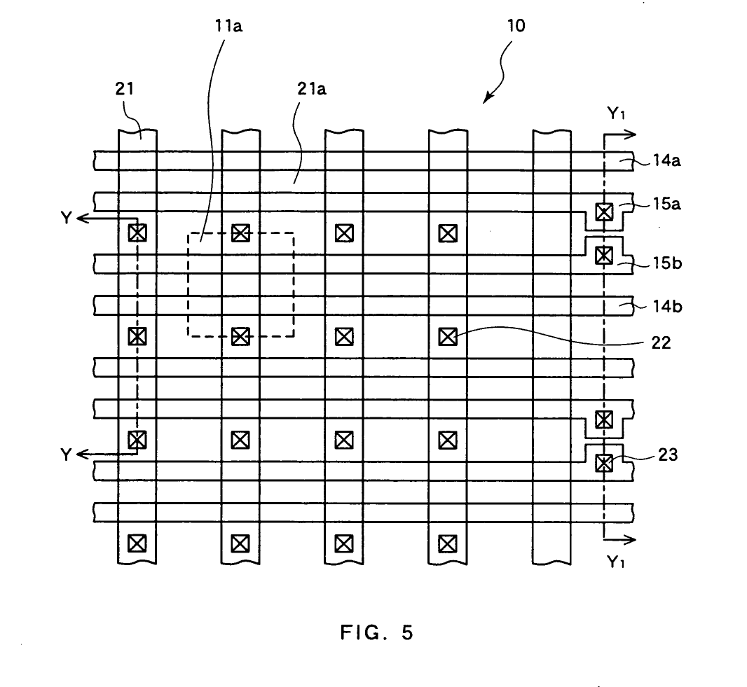

FIG. 5 shows a schematic plane view of nonvolatile memory cell array 10 in the third embodiment. Because the basic structure of the memory cell array is the same as that in the first embodiment as shown in FIG. 2, only different portions are explained. As shown FIG. 5, a control gate contact 23 is formed at the widened portion of select gate lines 15a and 15b. Select gate lines 15a and 15b made of the second gate electrode film is connected to the control gate electrode (not illustrated) in the select transistor. The floating gate electrode film (not illustrated) made of the first gate electrode film is formed beneath the layered gate electrode of the second gate electrode film. The control gate contact 23 connects between select gate lines 15a and 15b and the floating gate electrode film.

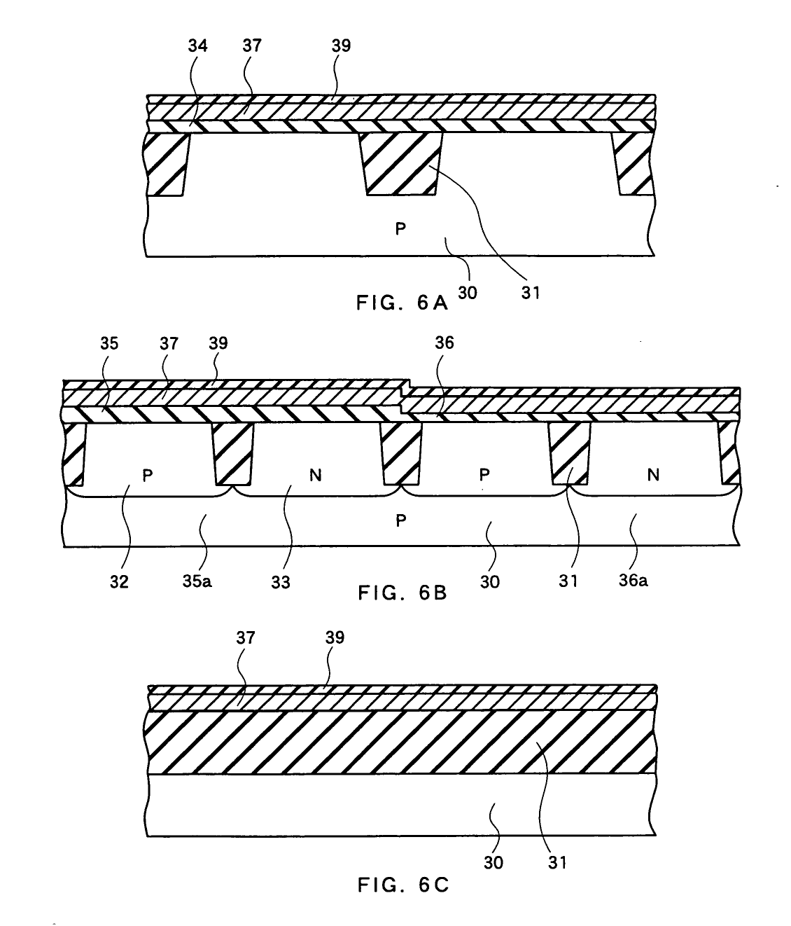

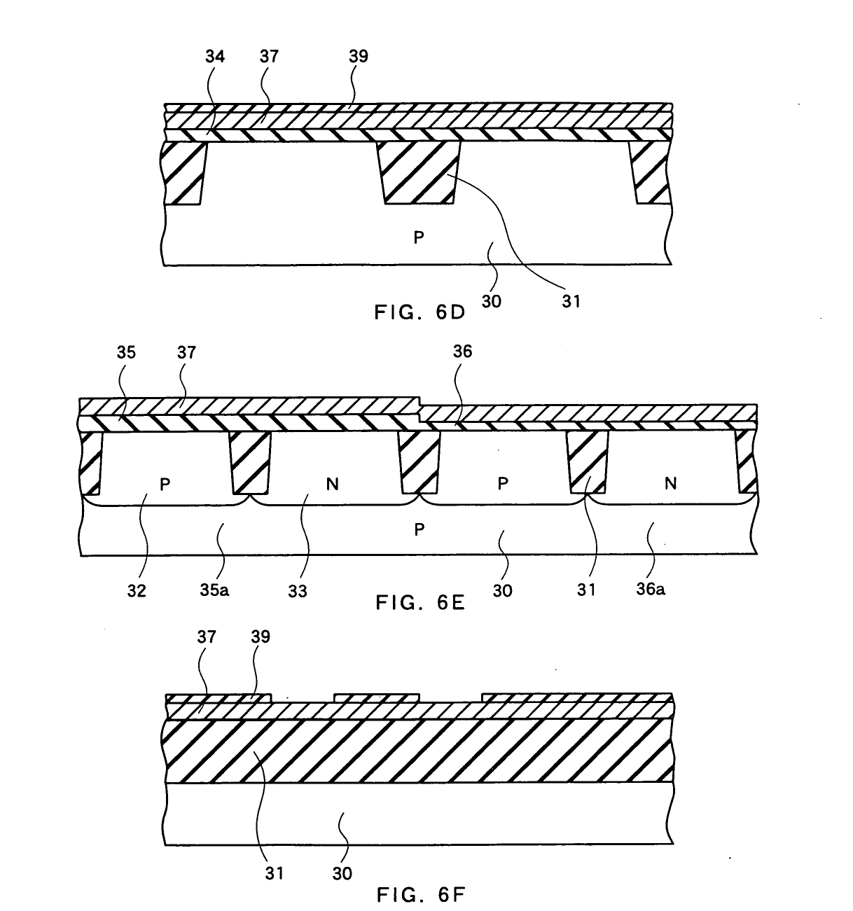

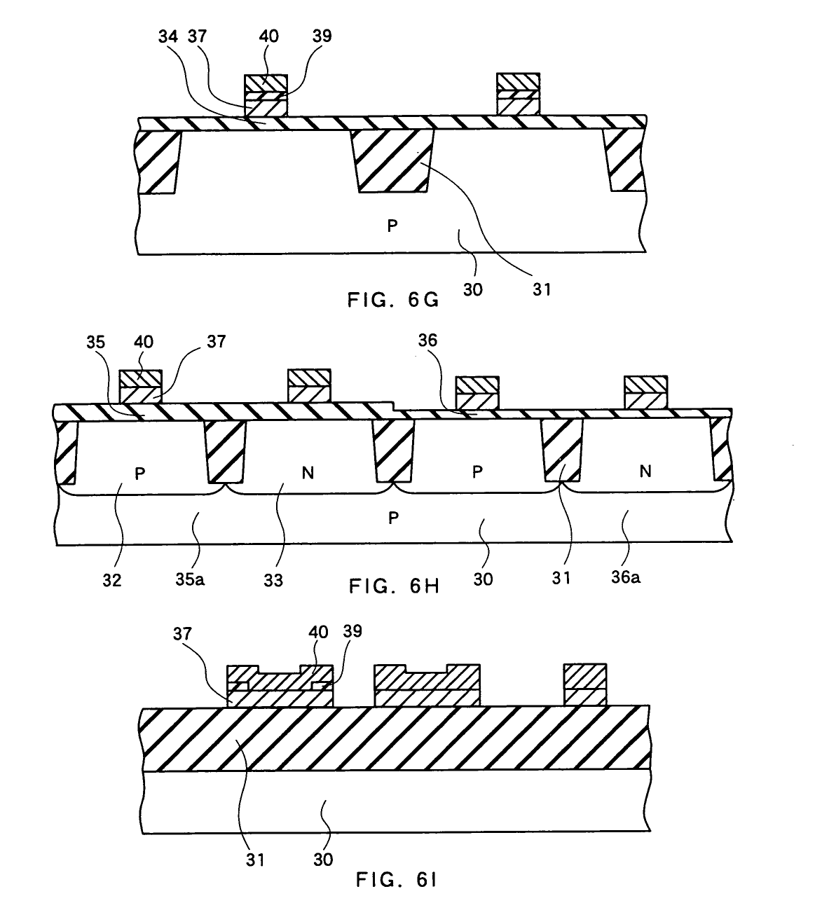

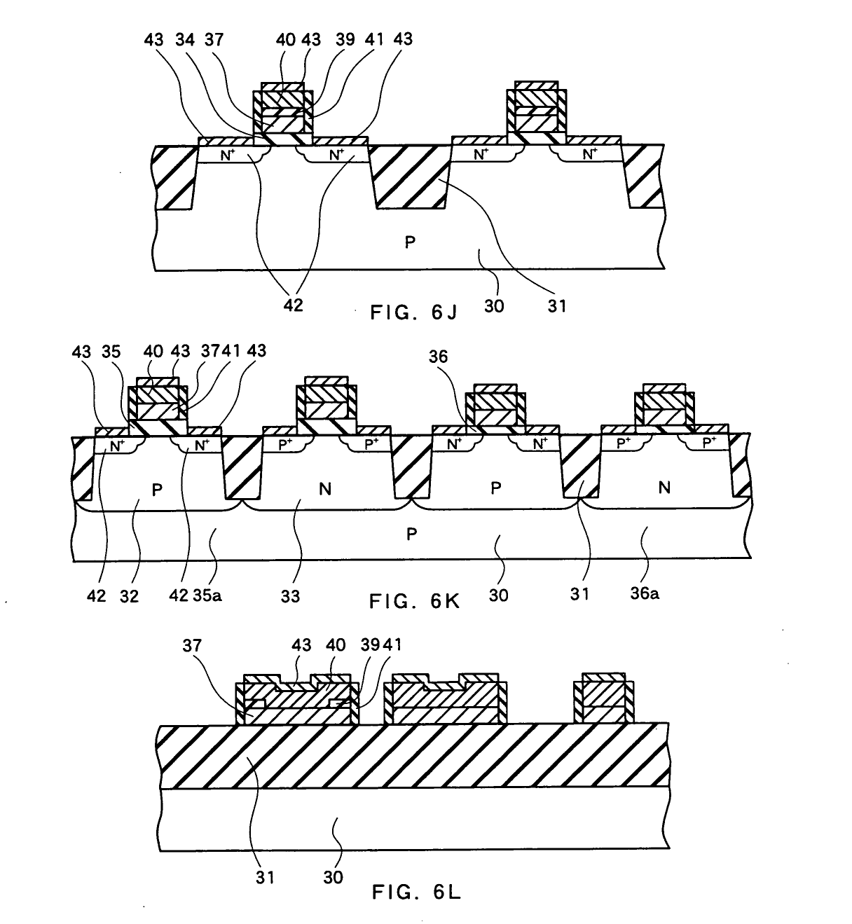

FIGS. 6A to 6L are cross-sectional views showing fabrication steps of a semiconductor device in the third embodiment of the present invention. The steps from the starting point to the process forming the inter-gate insulating film are the same as the first embodiment shown in FIG. 3A to 3J. Accordingly, explanation of these steps is skipped and the subsequent steps are described.

Pairs of cross sections in the nonvolatile memory are shown in FIGS. 6A to 6L. In other word, FIGS. 6A, 6D, 6G and 6J show enlarged cross-sectional views in the nonvolatile memory along the line Y-Y of FIG. 5. On the other hand, FIGS. 6C, 6F, 6I and 6L show enlarged cross-sectional views in the nonvolatile memory along the line Y₁-Y₁ in FIG. 5. Moreover, FIGS. 6B, 6E, 6H and 6K show cross-sectional views in the CMOS logic circuit. FIGS. 6J, 6K and 6L show cross-sectional views of a semiconductor device in the third embodiment of the present invention.

A silicon substrate 30 is prepared as a silicon substrate. As shown in FIG. 6A, a layered structure of a tunnel gate insulating film 34, a first gate electrode film 37 and an inter-gate insulating film 39 is formed on the silicon substrate 30 in the Y-Y direction of the nonvolatile memory in FIG. 5.

As shown in FIG. 6C, a layered structure of the first gate electrode film 37 and the inter-gate insulating film 39 is formed on the element isolation region 21 in the Y₁-Y₁ direction of the nonvolatile memory in FIG. 5.

As shown in FIG. 6B, in a CMOS logic circuit region, a layered structure of a first gate insulating film 35 or a second gate insulating film 36, and the first gate electrode film 37 is formed on the silicon substrate 30.

99 The nonvolatile memory cell region as shown in FIG. 6D is selectively covered with a mask. The control gate contact 23, as shown in FIG. 5, in the inter-gate insulating film 39 on the first gate electrode film 37 is selectively opened by using lithography and dry etching as shown in FIG. 6F. The inter-gate insulating film 39 of the CMOS logic circuit region is also removed with the step of the opening formation by etching as shown in FIG. 6E.

A second gate electrode film 40 made of a polycrystalline silicon film or an amorphous silicon film is formed over the silicon substrate 30 by using LPCVD. The second gate electrode film 40 is approximately 30 nm thick. As the inter-gate insulating film 39 on the first gate electrode film 37 in the nonvolatile memory cell region is selectively removed, the second gate electrode film 40 is connected to the first gate electrode film 33 as shown FIG. 6I. The second gate electrode film 40 and first gate electrode film 37 is selectively delineated by using lithography and dry etching. The layered structure, i.e. second gate electrode film 40 stacked on the first gate electrode film 37, is formed in the CMOS logic circuit region as shown in FIG. 6H.

The second gate electrode film 40 of the nonvolatile memory cell region and the second gate electrode film 40 and the first gate electrode film 37 of the CMOS logic circuit region are selectively delineated by using lithography and dry etching. The CMOS logic circuit region is covered with a mask film (not illustrated). Inter-gate insulating film 39 and first gate electrode film 37 is selectively delineated by using lithography and dry etching, employing the second gate electrode film 40 as a mask. The mask film of the CMOS logic circuit region is removed by etching. As using steps mentioned above, the second gate electrode film 40 is connected to the first gate electrode film 38 and the gate structure of the CMOS logic circuit is formed.

As the further process steps are the same as those of the first embodiment, the steps will be simply explained.

Conductive impurities are introduced into the silicon substrate 30 by using ion implantation as shown in FIGS. 6J, 6K and 6L. The second gate electrode film 40 are used as a mask. Source-drain regions with a comparatively shallow junction depth (not illustrated) are formed. Boron ions for p-type impurities are implanted with a dose of 1E13 cm⁻² to 1E15 cm⁻². Phosphorus ions or arsenic ions for n-type impurities are implanted with a dose of 1E13 cm⁻² to 1E15 cm⁻².

An insulating film such as a silicon nitride is formed on the second gate electrode film 40 by using LPCVD. The surface region of the insulating film is removed by using dry etching. As a result, a sidewall insulating film 41 is selectively formed on a side surface of the layered structure as shown in 6J, 6K and 6L.

Conductive impurities are introduced into the silicon substrate 30 by using ion implantation, using the second gate electrode film 40 and the sidewall insulating film 41 as a mask. The source-drain regions with a comparatively deep junction depth are formed. Boron for a p-type impurity is implanted with a dose of 1E15 cm⁻² to 1E16 cm⁻². Phosphorus or arsenic for an n-type impurity is implanted with a dose of 1E15 cm⁻² to 1E16 cm⁻². The source-drain regions 42 including also the comparatively the shallow region described previously, is finally formed as shown in FIG. 6J, 6K and 6L.

A cobalt film is formed on the silicon substrate 30. A cap film, such as Ti or TiN, may be further formed on the cobalt film, as required. By subsequent thermal annealing, cobalt-salicide electrode film 43 is formed on the second gate electrode film 40 and the source-drain regions 42 as shown in FIG. 56J, 6K and 6L.

A silicon oxide film (not illustrated) is formed on silicon substrate 30 by using plasma-assisted CVD. Contact holes are opened in the silicon oxide film. A metal interconnection including a bit line is formed. Furthermore, the formation of the silicon oxide, the contact holes, and the metal interconnection are carried out, as required. A multilevel interconnection can be formed.

The surface of the silicon substrate 30 is covered with a protective insulating film. Pad portions may be opened to finish a semiconductor device including the nonvolatile memory.

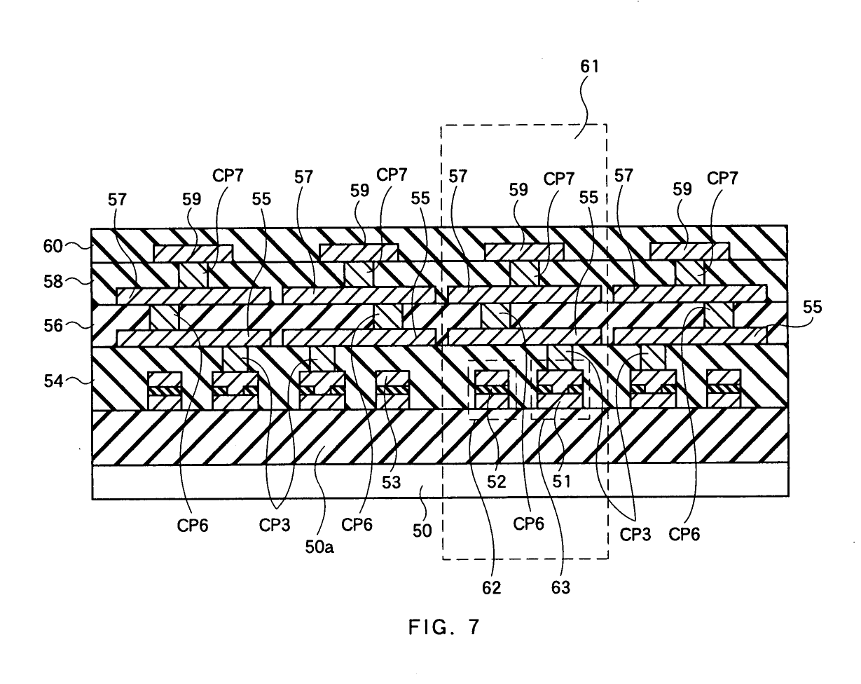

The cross sectional view of the semiconductor device including the nonvolatile memory in the third embodiment is shown in FIG. 7. A memory cell 61 having a select transistor 62 with the opening in the inter-gate insulating film and a memory transistor 63 is arranged. The multilevel interconnection constructed by metal layers 55, 57, 59 is formed in the inter-layer insulating films 54, 56, 58, 60. The contact plugs cp3, cp6, cp7 connect between the metal layers 55, 57, 59.

According to the third embodiment, following advantage is obtained in addition to the advantages previously described in the first embodiment. As the second gate electrode film connect to the first gate electrode film in the nonvolatile memory cell, the select gate in the select transistor is easily connected to upper metal interconnections.

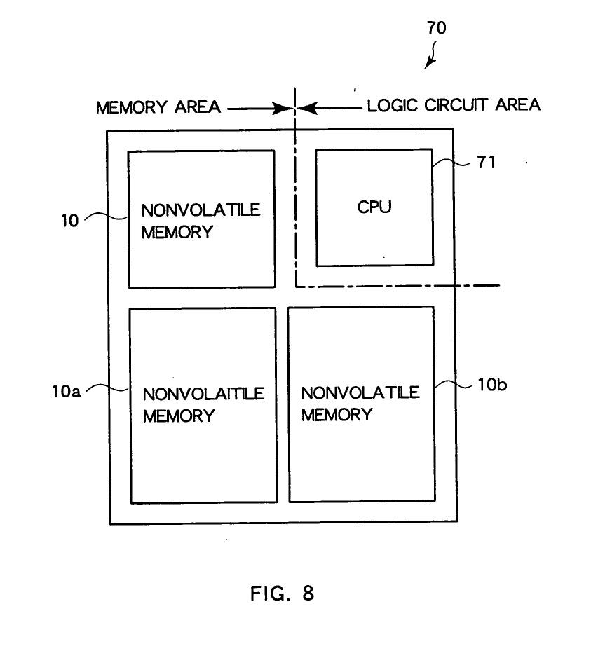

A fourth embodiment of present invention is hereinafter explained. FIG. 8 shows a block diagram of a system LSI in the fourth embodiment of the present invention. The fourth embodiment is a system LSI including a CPU and a plurality of nonvolatile memory circuits.

The system LSI 70 has a logic circuit area and a memory area. For example, a CPU 71 is formed in the logic circuit area. Three kinds of nonvolatile memories are formed in the memory area. Three kinds of nonvolatile memories are a nonvolatile memory 10 having a memory cell unit formed from two transistors explained in the first embodiment, the second embodiment and the third embodiment, a NAND-type nonvolatile memory 10a and a nonvolatile memory 10b having a memory cell unit formed of the three transistors.

In the system LSI 70, the nonvolatile memory 10 having a memory cell unit formed of two transistors and the CPU 71 are included in the same chip, so the nonvolatile memory 10 can be used as a read-only memory, which stores the firmware of the CPU 71.

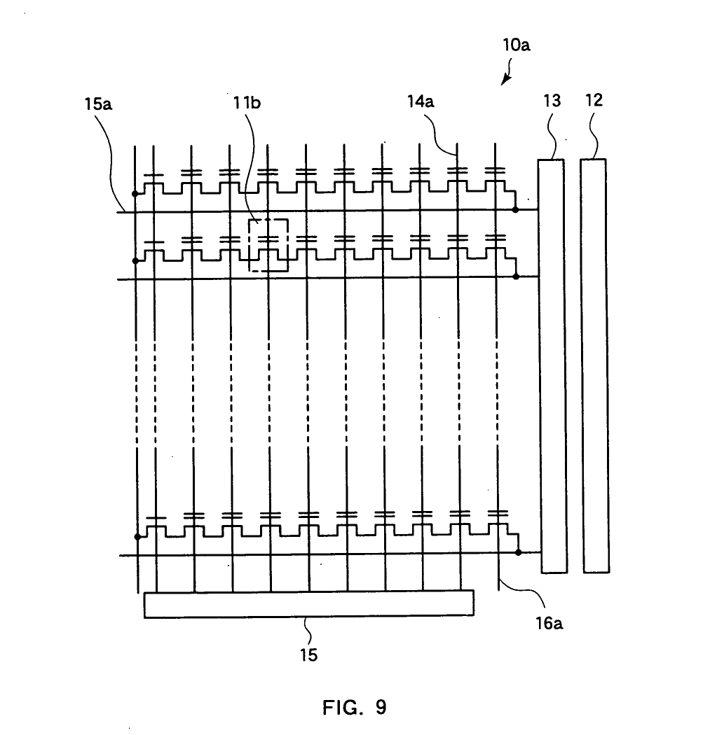

The circuit block diagram of the NAND-type nonvolatile memory 10a in the system LSI 70 is shown in FIG. 9. A memory cell 11b is formed of one transistor having a layered gate structure. A column decoder 12, a sense amplifier 13 and a low decoder 15 are formed in the periphery area.

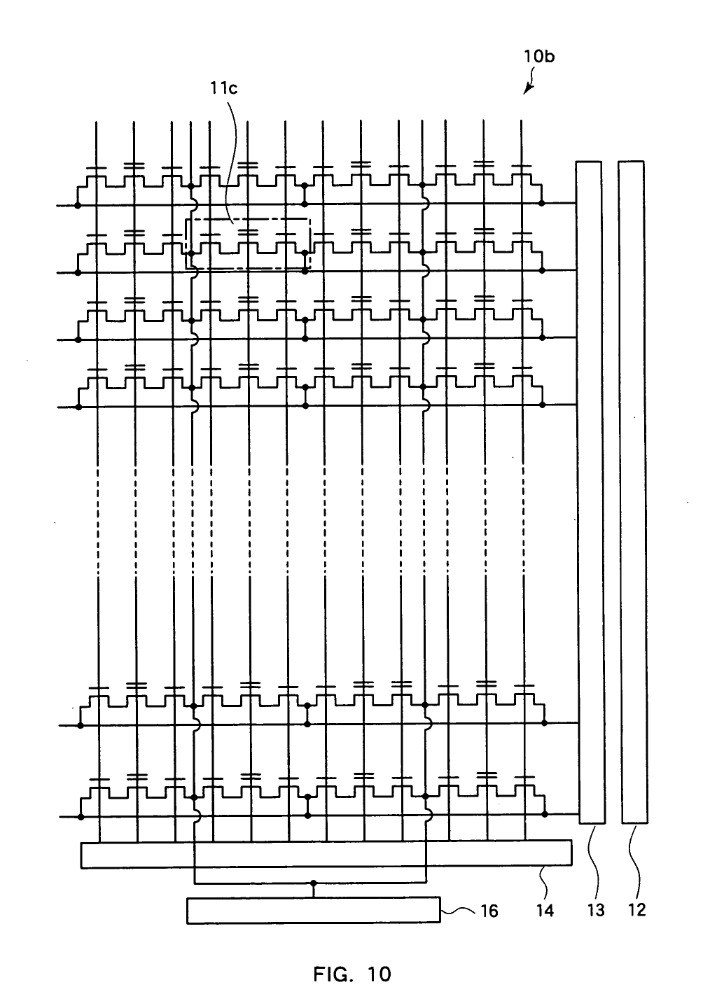

The circuit block diagram of the nonvolatile memory 10b having a memory cell unit formed of the three transistors in the system LSI 70 is shown in FIG. 10. A memory cell 11c is formed of one memory cell transistor having a layered gate structure and two select transistors sandwiched the memory cell transistor. The column decoder 12, the sense amplifier 13, the low decoder 14 and the source line driver 16 are formed in the periphery area of the memory device.

A fabrication method of the system LSI 70 is fundamentally the same as that of the semiconductor device described with the first embodiment, and consequently, the system LSI 70 can be easily fabricated for a semiconductor device.

The nonvolatile memory 10 having a memory cell unit formed of the two transistors, the NAND-type nonvolatile memory 10a and the nonvolatile memory 10b having a memory cell unit formed of the three transistors can be basically fabricated by the same processing steps and the same conditions, which leads to simplify the fabrication steps of the system LSI 70.

Moreover, it is also possible to apply the above-mentioned fabrication method to a semiconductor device, which contains independently the NAND-type nonvolatile memory 10a or a nonvolatile memory, such as NOR-type nonvolatile memory, NANO-type nonvolatile memory or AND-type nonvolatile memory.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

For example, the first gate insulating film, the second gate insulating film and the tunnel gate insulating film may be not only the silicon oxide film and the silicon nitride film but also a silicon oxy-nitride film which contains both oxygen and nitrogen by various composition or a metal oxide film having higher dielectric constant such as a hafnium oxide film, a zirconium oxide film, a titanium oxide film, an aluminum oxide film, the compound film of those oxide films and a layered film of those oxide films.

Furthermore, by using the high concentration n-type silicon as a gate electrode material including the first gate electrode film and the second gate electrode film, applications as semiconductor devices may be performed comparatively easily.

Moreover, a material of the salicide film formed on the gate electrode and the source and drain region may be not Co but Ti, Ni, W, Ta and Mo, etc. The gate electrode film of layered structure including the silicide of the above-mentioned metals or nitrides of those can also be formed.

Metal interconnection can be chosen from Al, Cu, Au, Ag, and W, etc. Moreover, underlying barrier metal beneath the metal interconnection may lead to an advantage, such as adhesion with an insulating layer and reaction suppression in a contact area. In this case, a metal such as W, Mo, Ti etc., a metal silicide such as W-silicide, Mo-silicide, Ti-silicide, etc. and a metal nitride such as W-nitride, Mo-nitride, and Ti-nitride etc. may be formed for layered structure.

As p-type silicon substrate 30 is used in the embodiments, a p-type well need not be formed in the nonvolatile memory area. As required, a p-type well is formed in the nonvolatile memory area by using ion-implantation. In this case, the well structure may be a double well structure having a p-type well within an n-type well.

In addition to a silicon substrate, compound semiconductor substrates such as a SOI substrate and GaAs substrate etc. can be used as a semiconductor substrate. The layered structure can be applied not to the nonvolatile memory but to other kinds of semiconductor devices. Moreover, the nonvolatile memory can be applied to both solo nonvolatile memory and a semiconductor device mixed with various logic circuits.

1. A semiconductor device, comprising:
a semiconductor substrate;
a nonvolatile memory cell including a first MOS transistor having a first gate formed on the semiconductor substrate, and source-drain regions formed in the semiconductor substrate to interpose a surface region of the semiconductor substrate beneath the first gate, the first gate being a layered gate structure having a tunnel gate insulating film, a first gate electrode film, an inter-gate insulating film and a second gate electrode film; and
a logic circuit including a second MOS transistor having a second gate formed on the semiconductor substrate, and the source-drain regions formed in the semiconductor substrate to interpose a surface region of the semiconductor substrate beneath the second gate, the second gate being a gate structure having a gate insulating film, the first gate electrode film and the second gate electrode film.

2. A semiconductor device according to claim 1, wherein
an opening is formed in the inter-gate insulating film, and the second gate electrode film is connected to the first gate electrode film at the opening.

3. A semiconductor device according to claim 1, wherein
the nonvolatile memory cell includes two kinds of first MOS transistors, each of the first MOS transistors being a memory cell transistor and a select transistor, and a source region of the source-drain regions in the memory cell transistor being connected to a drain region of the source-drain regions in the select transistor.

4. A semiconductor device according to claim 1, wherein
the first gate electrode film and the second gate electrode film of the first MOS transistor is a n-type silicon film,
the first gate electrode film and the second gate electrode film of a n-type MOS transistor in the second MOS transistors is a n-type silicon film, and
the first gate electrode film and the second gate electrode film of a p-type MOS transistor in the second MOS transistors is a p-type silicon film.

5. A semiconductor device according to claim 1, further comprising
a metal-silicide film formed on the source and the drain.

6. A semiconductor device according to claim 2, further comprising
an ultra-thin insulating film formed between the second gate electrode film and the first gate electrode film.

7. A semiconductor device according to claim 1, wherein
the gate insulating film includes a first gate insulating film and a second gate insulating film,and
the thickness of the first gate insulating film is different from the thickness of the second gate insulating film.

8. A semiconductor device according to claim 2, wherein
the opening is formed in the inter-gate insulating film of the select transistor, and the second gate electrode film is connected to the first gate electrode film at the opening.

9. A method of fabricating a semiconductor device, comprising:
forming an element isolation area surrounding an element area in a semiconductor substrate;
forming a tunnel gate insulating film on the element area;
removing the tunnel gate insulating film on a logic circuit region having CMOS logic circuits in the element area;
forming a gate insulating film on the logic circuit region in the element area;
forming a first gate electrode film on the tunnel gate insulating film and the gate insulating film;
selectively removing the first gate electrode film and the tunnel gate insulating film on the nonvolatile memory cell region in the element area;
forming an inter-gate insulating film on the first gate electrode film of the nonvolatile memory cell region;
forming a second gate electrode film on the inter-gate insulating film of the nonvolatile memory cell region and the first gate electrode film of the logic circuit region;
introducing conductive impurities into the second gate electrode film;
selectively removing the second gate electrode film, the inter-gate insulating film and the first gate electrode film of the nonvolatile memory cell region, and the second gate electrode film and the first gate electrode film of the logic circuit region; and
forming source-drain regions in the semiconductor substrate to interpose a surface region of the semiconductor substrate beneath the tunnel gate insulating film and the gate insulating film, by introducing conductive impurities into the semiconductor substrate using the second gate electrode film as a mask.

10. A method of fabricating a semiconductor device, according to claim 9, further comprising
forming an opening in the inter-gate insulating film between forming the inter-gate insulating film and forming the second gate electrode film.

11. A method of fabricating a semiconductor device, according to claim 9, wherein
forming the second gate electrode film includes forming a silicon film doped with n-type impurities.

12. A method of fabricating a semiconductor device, according to claim 9, wherein
forming the second gate electrode film includes forming a non-doped silicon film,
introducing conductive impurities into the second gate electrode film includes introducing p-type impurities into the second gate electrode film of a p-type MOS transistor in the logic circuit region, n-type impurities into the second gate electrode film of an n-type MOS transistor in the logic circuit region and n-type impurities into the second gate electrode film of the nonvolatile memory cell region.

13. A method of fabricating a semiconductor device, according to claim 9, further comprising
forming a metal-silicide film on the source-drain region.

14. A method of fabricating a semiconductor device, according to claim 10, further comprising
forming an ultra-thin gate insulating film on the first gate insulating film between forming the opening in the inter-gate insulating film and forming the second gate electrode film.

15. A method of fabricating a semiconductor device, according to claim 9, wherein
the gate insulating film includes two kinds of gate insulating films being formed to have different film thickness, respectively.

16. A method of fabricating a semiconductor device, according to claim 9, wherein
forming the inter-gate insulating film on the second gate electrode film of the nonvolatile memory cell region includes forming the inter-gate insulating film over the silicon substrate and selectively removing the inter-gate insulating film on the first gate electrode film of the logic circuit region.
